(19) United States
(12) Patent Application Publication
(10) Pub. No.: US 2025/0234660 A1
(43) Pub. Date: Jul. 17, 2025

(54) IMAGE SENSOR

(71) Applicant: SAMSUNG ELECTRONICS CO., LTD., Suwon-si (KR)

(72) Inventors: Kijoong YOON, Suwon-si (KR); Hajin LIM, Suwon-si (KR); Jaesung HUR, Suwon-si (KR); Jeongha SHIN, Suwon-si (KR); Jongmin JEON, Suwon-si (KR)

(73) Assignee: SAMSUNG ELECTRONICS CO., LTD., Suwon-si (KR)

(21) Appl. No.: 18/974,015

(22) Filed: Dec. 9, 2024

(30) Foreign Application Priority Data
Jan. 17, 2024 (KR) 10-2024-0007640

(51) Int. Cl. H01L 27/146

(52) U.S. Cl. CPC H10F 39/8053; H10F 39/024; H10F 39/182

(57) ABSTRACT

An image sensor includes a substrate including a photoelectric conversion region, a first color filter above the substrate, a second color filter adjacent to the first color filter in a first horizontal direction, and above the substrate, a plurality of liner layers on an upper surface and a sidewall of each of the first color filter and the second color filter, an air gap between the first color filter and the second color filter, and a capping layer on the upper surface of each of the first color filter and the second color filter.

### CROSS-REFERENCE TO RELATED APPLICATION

This application claims benefit of priority under 35 U.S.C. § 119 to Korean Patent Application No. 10-2024-0007640, filed on Jan. 17, 2024, in the Korean Intellectual Property Office, the disclosure of which is incorporated by reference herein in its entirety.

### BACKGROUND

### 1. Field

The present disclosure relates generally to an image sensor, and more particularly, to an image sensor with color filters isolated by an air gap.

### 2. Description of Related Art

An image sensor may refer to a device that may convert an optical image into an electrical signal. Examples of image sensors may include, but not be limited to, charge coupled device (CCD) type image sensors, complementary metal-oxide-semiconductor (CMOS) type image sensors (CIS), or the like. These image sensors may be equipped with a plurality of pixels arranged in the form of a two-dimensional (2D) matrix, and each pixel may output an image signal corresponding to an incident light energy. Each of the plurality of pixels may accumulate photoelectric charges corresponding to the amount of light incident through a photoelectric conversion element and may output a pixel signal based on the accumulated photoelectric charges. Recently, as the degree of integration of image sensors may increase, the size of pixels may be decreasing and/or the size of components of pixel circuits may also be decreasing.

### SUMMARY

One or more example embodiments of the present disclosure provide an image sensor with improved reliability and performance, when compared to related image sensors.

According to an aspect of the present disclosure, an image sensor includes a substrate including a photoelectric conversion region, a first color filter above the substrate, a second color filter adjacent to the first color filter in a first horizontal direction, and above the substrate, a plurality of liner layers on an upper surface and a sidewall of each of the first color filter and the second color filter, an air gap between the first color filter and the second color filter, and a capping layer on the upper surface of each of the first color filter and the second color filter.

According to an aspect of the present disclosure, an image sensor includes a substrate including a photoelectric conversion region, a first color filter above the substrate, a second color filter adjacent to the first color filter in a first horizontal direction, and above the substrate, a first trench between the first color filter and the second color filter, a first plurality of liner layers conformally disposed on a bottom surface of the first trench, a first sidewall of the first trench, and a second sidewall of the first trench, a first air gap in the first trench, and a plurality of capping layers on the first air gap, a top surface of the first color filter, and a top surface of the second color filter.

According to an aspect of the present disclosure, an image sensor includes a substrate including a photoelectric conversion region, a first color filter above the substrate, a second color filter adjacent to the first color filter in a first horizontal direction, above the substrate, a third color filter adjacent to the first color filter in a second horizontal direction crossing the first horizontal direction, a first trench between the first color filter and the second color filter, a second trench between the second color filter and the third color filter, a plurality of liner layers conformally disposed on a bottom surface of the first trench, a first sidewall of the first trench, a second sidewall of the first trench, a bottom surface of the second trench, a first sidewall of the second trench, and a second sidewall the second trench, a first air gap in the first trench, and a plurality of capping layers on a top surface of the first color filter, a top surface of the second color filter, a top surface of the third color filter, and in the second trench.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings.

FIG. 1 is a circuit diagram of an image sensor, according to embodiments.

FIG. 2 is a plan view illustrating an image sensor, according to embodiments.

FIG. 3 is a cross-sectional view taken along line I-I′ of FIG. 2, according to embodiments.

FIG. 4 is a cross-sectional view of a pixel array region of an image sensor, according to embodiments.

FIG. 5 is a cross-sectional view taken along line P-P′ of FIG. 4, according to embodiments.

FIG. 6 is a cross-sectional view taken along line Q-Q′ of FIG. 4, according to embodiments.

FIG. 7A is a cross-sectional view taken along line A-A′ of FIGS. 5 and 6, according to embodiments.

FIG. 7B is a cross-sectional view taken along line B-B′ of FIGS. 5 and 6, according to embodiments.

FIG. 8 is an enlarged cross-sectional view of a region EX1 of FIG. 7A, according to embodiments.

FIG. 9 is an enlarged cross-sectional view of a region EX2 of FIG. 7B, according to embodiments.

FIG. 10 is a cross-sectional view of a pixel array region of an image sensor, according to embodiments.

FIG. 11 is a cross-sectional view of a pixel array region of an image sensor, according to embodiments.

FIGS. 12A to 18B are cross-sectional views illustrating a process of manufacturing an image sensor, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlO”, “HfO”, “SiN”, “SiO”, “SiON”, and the like may refer to a material made of elements included in each of the terms and is not a chemical formula representing a stoichiometric relationship.

Hereinafter, various embodiments of the present disclosure are described with reference to the accompanying drawings.

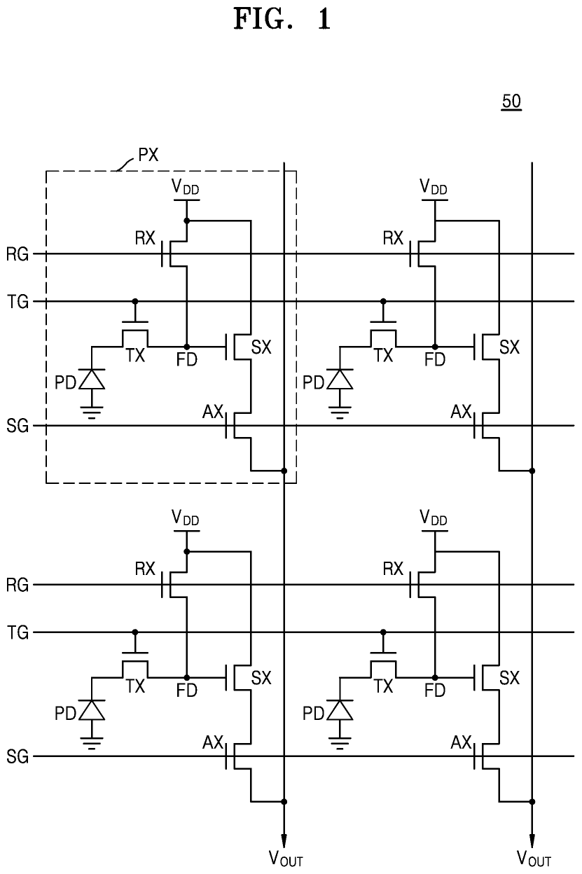

FIG. 1 is a circuit diagram of an image sensor 50, according to embodiments.

Referring to FIG. 1, each of unit pixel regions PX of the image sensor 50 may include a photoelectric conversion region PD, a transmission transistor TX, a source follower transistor SX, a reset transistor RX, and a selection transistor AX. The transmission transistor TX, the reset transistor RX, and the selection transistor AX may include a transmission gate TG, a reset gate RG, and a selection gate SG, respectively.

The photoelectric conversion region PD may be and/or may include a photodiode including an n-type impurity region and a p-type impurity region. The floating diffusion region FD may function as a drain of the transmission transistor TX. The floating diffusion region FD may function as a source of the reset transistor RX. The source follower transistor SX may be connected to the selection transistor AX.

The operation of the image sensor 50 is described below with reference to FIG. 1. When light is blocked, a power voltage V_{DD} may be applied to the drain of the reset transistor RX and the drain of the source follower transistor SX, and the reset transistor RX may be turned on to release charges remaining in the floating diffusion region FD. When the reset transistor RX is turned off and light from the outside is incident into the photoelectric conversion region PD, an electron-hole pair may be generated in the photoelectric conversion region PD. Holes may be accumulated by moving to the p-type impurity region of the photoelectric conversion region PD, and electrons may be accumulated by moving to the n-type impurity region. When the transmission transistor TX is turned on, charges, such as electrons and holes, may be transferred to the floating diffusion region FD and accumulated. The gate bias of the source follower transistor SX may change in proportion to the accumulated amount of charge, resulting in a change in the source potential of the source follower transistor SX. When the selection transistor AX is turned on, a signal V_{OUT} caused by electric charges may be read through a column line.

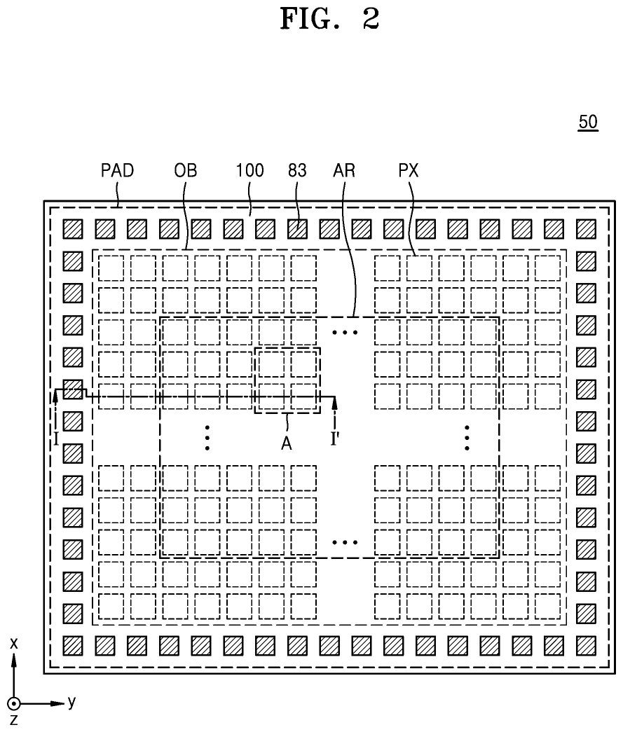

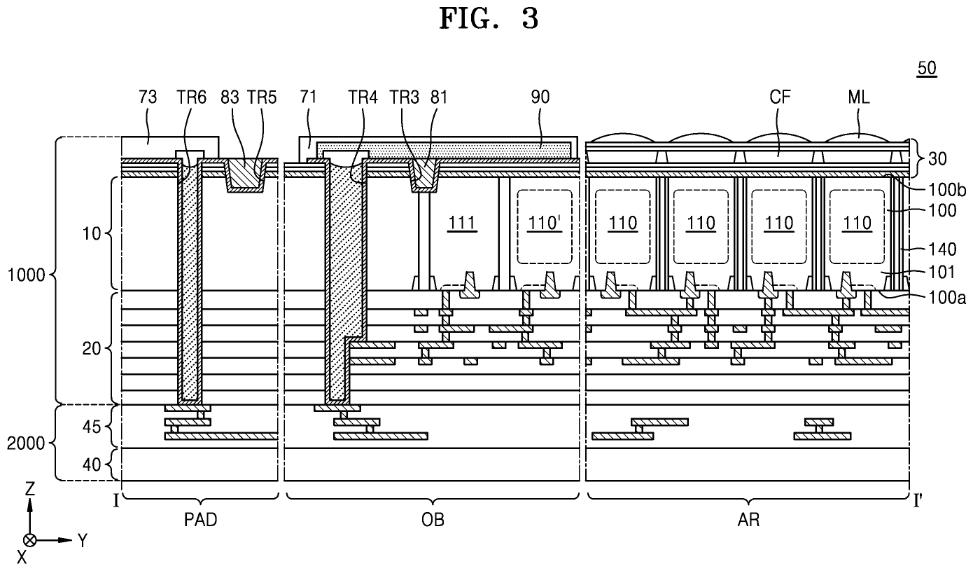

A wiring line may be electrically connected to at least one of the transmission gate TG, the reset gate RG, and the selection gate SG. The wiring line may be configured to apply a power voltage V_{DD} to a drain of the reset transistor RX or a drain of the source follower transistor SX. The wiring line may include a column line connected to the selection transistor AX. The wiring lines may be wirings as described with reference to FIGS. 2 and 3.

Although a pixel including one photoelectric conversion region PD and four (4) transistors (e.g., the transmission transistor TX, the reset transistor RX, the selection transistor AX, and the source follower transistor SX) is illustrated in FIG. 1, the present disclosure not limited thereto. For example, multiple pixels may be provided, and the reset transistor RX, the source follower transistor SX, or the selection transistor AX may be shared with each other by neighboring pixels. Accordingly, the degree of integration of the image sensor 50 may be improved, when compared to a related image sensor.

FIG. 2 is a plan view illustrating the image sensor 50, according to embodiments. FIG. 3 is a cross-sectional view taken along line I-I′ of FIG. 2, according to embodiments.

Referring to FIGS. 2 and 3, the image sensor 50 may include a sensor chip 1000 and a logic chip 2000. The sensor chip 1000 may include a photoelectric conversion layer 10, a first wiring layer 20, and a light transmission layer 30. The photoelectric conversion layer 10 may include a substrate 100, unit pixel regions 101 provided in the substrate 100, and photoelectric conversion regions 110 provided in the unit pixel regions 101. Light incident from the outside may be converted into an electrical signal in the photoelectric conversion regions 110.

The substrate 100 may include a pixel array region AR, an optical black region OB, and a pad region PAD from a plan view. A pixel array region AR may be arranged at a center portion of the substrate 100 in a plan view. The pixel array region AR may include a plurality of unit pixel regions PX. The unit pixel regions PX may output a photoelectric signal from incident light. The unit pixel regions PX may form columns and rows, and may be two-dimensionally (2D) arranged. The columns may be parallel to a first horizontal direction (X direction). The rows may be parallel to a second horizontal direction (Y direction). In the present disclosure, the first horizontal direction (X direction) may be parallel to a first surface 100a of the substrate 100. The second horizontal direction (Y direction) may be parallel to the first surface 100a of the substrate 100 and may be different from the first horizontal direction (X direction). For example, the second horizontal direction (Y direction) may be substantially perpendicular to the first horizontal direction (X direction). A third direction (Z direction) may be substantially perpendicular to the first surface 100a of the substrate 100.

A pad region PAD may be provided at an edge portion of the substrate 100 and may surround the pixel array region AR in a plan view. Second pad terminals 83 may be provided on the pad region PAD. The second pad terminals 83 may output electrical signals generated in the unit pixel regions PX to the outside. Alternatively or additionally, an external electrical signal and/or voltage may be transmitted to the unit pixel regions PX through the second pad terminals 83. Since the pad region PAD is arranged at the edge portion of the substrate 100, the second pad terminals 83 may be easily connected to the outside.

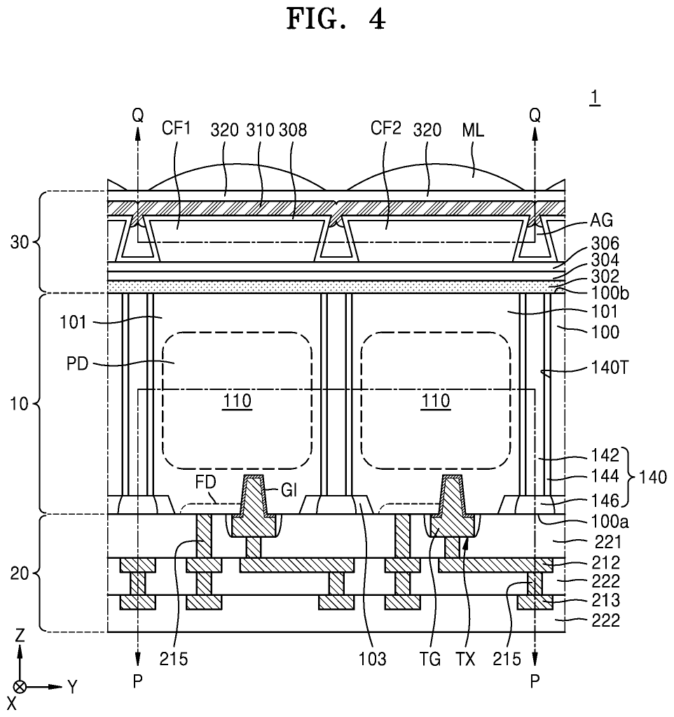

An optical black region OB may be arranged between the pixel array region AR and the pad region PAD of the substrate 100. The optical black region OB may surround the pixel array region AR in a plan view. The optical black region OB may include a plurality of dummy regions 111. The signals generated in the dummy regions 111 may be used as information for removing process noise thereafter. Hereinafter, the pixel array region AR of an image sensor is described with reference to FIG. 4.

FIG. 4 is a cross-sectional view of a pixel array region of an image sensor 1, according to embodiments.

The image sensor 1 may include and/or may be similar in many respects to the image sensor 50 described above with reference to FIGS. 1 to 3, and may include additional features not mentioned above. Consequently, repeated descriptions of the image sensor 1 described above with reference to FIGS. 1 to 3 may be omitted for the sake of brevity.

Referring to FIG. 4, the image sensor 1 may include a photoelectric conversion layer 10, a first wiring layer 20, and a light transmission layer 30. The photoelectric conversion layer 10 may include a substrate 100, a pixel isolation structure 140, and a device isolation pattern 103.

The substrate 100 may have a first surface 100a (or a front surface) and a second surface 100b (or a rear surface) opposite to each other. Light may be incident on the second surface 100b of the substrate 100. The first wiring layer 20 may be arranged on the first surface 100a of the substrate 100, and the light transmission layer 30 may be arranged on the second surface 100b of the substrate 100. The substrate 100 may be a semiconductor substrate or a silicon on insulator (SOI) substrate. The semiconductor substrate may include, for example, a silicon (Si) substrate, a germanium (Ge) substrate, or a silicon-germanium (Si—Ge) substrate. The substrate 100 may include first conductivity type impurities. For example, the first conductivity type impurities may include p-type impurities such as, but not limited to, aluminum (Al), boron (B), indium (In), gallium (Ga), or the like.

The substrate 100 may include unit pixel regions 101 including photoelectric conversion regions 110. The photoelectric conversion regions 110 may be and/or may include partial regions of the photoelectric conversion regions 110 described with reference to FIG. 3. The unit pixel regions 101 may be and/or may include partial regions of the unit pixel regions 101 described with reference to FIG. 3. The photoelectric conversion regions 110 may be provided in the unit pixel regions 101 in the substrate 100. The photoelectric conversion regions 110 may perform a substantially similar and/or the same function and role as the photoelectric conversion region PD of FIG. 1. The photoelectric conversion regions 110 may be regions doped with impurities of a second conductivity type in the substrate 100. The impurities of the second conductivity type may have a conductivity type opposite to the impurities of the first conductivity type. The second conductivity type impurities may include n-type impurities such as, but not limited to, phosphorus (P), arsenic (As), bismuth (Bi), antimony (Sb), or the like. The photoelectric conversion regions 110 may be adjacent to a first surface 100a of the substrate 100. That is, the photoelectric conversion regions 110 may be arranged closer to the first surface 100a than the second surface 100b. For example, each of the photoelectric conversion regions 110 may include a first region adjacent to the first surface 100a and a second region adjacent to the second surface 100b. An impurity concentration difference between the first region and the second region of the photoelectric conversion regions 110 may be provided. Accordingly, the photoelectric conversion regions 110 may have a potential slope between the first surface 100a and the second surface 100b of the substrate 100. As another example, the photoelectric conversion regions 110 may not have a potential slope between the first surface 100a and the second surface 100b of the substrate 100.

The substrate 100 and the photoelectric conversion regions 110 may constitute a photodiode. That is, the photodiode may be constructed by the p-n junction of the substrate 100 of the first conductivity type and the photoelectric conversion regions 110 of the second conductivity type. The photoelectric conversion regions 110 constituting the photodiode may generate and accumulate photo charges in proportion to the intensity of incident light.

As shown in FIG. 4, pixel isolation structures 140 are provided in the substrate 100, and may define unit pixel regions 101. For example, the pixel isolation structure 140 may be provided between the unit pixel regions 101 of the substrate 100. From a plan view, the pixel isolation structure 140 may have a lattice structure. From a plan view, the pixel isolation structure 140 may completely surround each of the unit pixel regions 101. The pixel isolation structure 140 may be provided in a pixel isolation trench 140T, and the pixel isolation trench 140T may be recessed from the first surface 100a of the substrate 100. The pixel isolation structure 140 may extend from the first surface 100a of the substrate 100 toward the second surface 100b thereof. The pixel isolation structure 140 may be a deep trench isolation layer. The pixel isolation structure 140 may pass through the substrate 100. The vertical height of the pixel isolation structure 140 may be substantially similar and/or the same as the vertical thickness of the substrate 100. For example, the width of the pixel isolation structure 140 may gradually decrease from the first surface 100a to the second surface 100b of the substrate 100.

The pixel isolation structure 140 may include a conductive layer 142, an insulating liner 144, and an upper insulating layer 146. The conductive layer 142 may be arranged inside the pixel isolation trench 140T penetrating the substrate 100. The insulating liner 144 may be arranged on an inner wall of the pixel isolation trench 140T penetrating the substrate 100, may extend from the first surface 100a to the second surface 100b of the substrate 100, and may be arranged between the conductive layer 142 and the substrate 100. The upper insulating layer 146 may be arranged in a portion of the pixel isolation trench 140T adjacent to the first surface 100a of the substrate 100.

In embodiments, the pixel isolation structure 140 may penetrate the substrate 100. For example, the pixel isolation structure 140 may be a front-side deep trench isolation (FDTI). In an embodiment, the pixel isolation structure 140 may not penetrate the substrate 100. For example, the pixel isolation structure 140 may be a back-side deep trench isolation (BDTI).

In embodiments, the conductive layer 142 may include, but not limited to, at least one of doped polysilicon, metal, metal silicide, metal nitride, and metal-containing layer. The insulating liner 144 may include an insulating material such as, but not limited to, silicon oxide (SiO), silicon nitride (SiN), or silicon oxynitride (SiON). The upper insulating layer 146 may include an insulating material such as, but not limited to, silicon oxide (SiO), silicon nitride (SiN), or silicon oxynitride (SiON).

According to an embodiment, the device isolation pattern 103 may be provided in the substrate 100. A bottom surface of the device isolation pattern 103 may be provided in the substrate 100. The width of the device isolation pattern 103 may gradually decrease from the first surface 100a to the second surface 100b of the substrate 100. At least a portion of the device isolation pattern 103 may be arranged on the upper sidewall of the pixel isolation structure 140 and may be connected to the upper sidewall of the pixel isolation structure 140. The depth of the device isolation pattern 103 may be less than the depth of the pixel isolation structure 140. The device isolation pattern 103 may include, for example, silicon oxide (SiO), silicon nitride (SiN), and/or silicon oxynitride (SiON).

The transmission transistors TX described above with reference to FIG. 1 may be provided on the first surface 100a of the substrate 100. The transmission transistors TX may be electrically connected to the photoelectric conversion regions 110, respectively.

According to an embodiment, the first wiring layer 20 may include wiring insulating layers (e.g., a first wiring insulating layer 221 and a second wiring insulating layer 222), wirings (e.g., a first wiring 212 and a second wiring 213), and vias 215. The first wiring insulating layer 221 may cover the first surface 100a of the substrate 100. The first wiring insulating layer 221 may be provided between the first wiring 212 and the first surface 100a of the substrate 100. The second wiring insulating layers 222 may be stacked on the first wiring insulating layer 221. The first and second wiring insulating layers 221 and 222 may include a non-conductive material. For example, the first and second wiring insulating layers 221 and 222 may include silicon-based insulating materials such as, but not limited to, silicon oxide (SiO), silicon nitride (SiN), and/or silicon oxynitride (SiON).

The first and second wirings 212 and 213 may be provided on the first wiring insulating layer 221. That is, the first and second wirings 212 and 213 may be arranged in the second wiring insulating layers 222 stacked on the first surface 100a of the substrate 100. The first and second wirings 212 and 213 may be vertically connected to the transmission transistors TX through the vias 215. The electrical signals converted in the photoelectric conversion regions 110 may be signal-processed in the first wiring layer 20. In embodiments of the present disclosure, the first and second wirings 212 and 213 may be arranged regardless of the arrangement of the photoelectric conversion regions 110. That is, the first and second wirings 212 and 213 may cross upper portions of the photoelectric conversion regions 110. The first and second wirings 212 and 213 and the vias 215 may include a metal material, for example, copper (Cu), tungsten (W), or the like.

The light transmission layer 30 may include color filters CF (e.g., a first color filter CF1 and a second color filter CF2, hereinafter generally referred to as “CF”) and microlenses ML. The light transmission layer 30 may collect and filter light incident from the outside to provide light to the photoelectric conversion layer 10.

That is, color filters CF and microlenses ML may be provided on the second surface 100b of the substrate 100. The color filters CF may be arranged on the unit pixel regions 101, respectively. The microlenses ML may be arranged on the color filters CF, respectively. A rear insulating layer 302 and auxiliary insulating layers (e.g., first auxiliary insulating layers 304 and second auxiliary insulating layers 306) may be arranged between the second surface 100b of the substrate 100 and the color filters CF. The rear insulating layer 302 may cover the second surface 100b of the substrate 100. The rear insulating layer 302 may be in contact with the second surface 100b of the substrate 100. For example, the rear insulating layer 302 may include at least one of a bottom antireflective coating (BARC) layer, a fixed charge layer, an adhesive layer, and a protective layer. When the rear insulating layer 302 functions as the bottom antireflective layer, reflection of light may be prevented so that light incident on the second surface 100b of the substrate 100 may smoothly reach the photoelectric conversion regions 110. The rear insulating layer 302 and the first and second auxiliary insulating layers 304 and 306 may include a metal oxide (e.g., aluminum oxide (AlO) or hafnium oxide (HfO)) and/or a silicon-based insulating material (e.g., silicon oxide (SiO) or silicon nitride (SiN)).

The color filters CF may include primary color filters. For example, the color filters CF may include first to third color filters having different colors. For example, each of the first to third color filters may include green, red, or blue color filters. The first to third color filters may be arranged in a Bayer pattern manner. As another example, the first to third color filters may include color filters of other colors such as cyan, magenta, or yellow color filters.

A liner layer 308 covering top surfaces and sidewalls of the color filters CF may be provided. The liner layer 308 may be arranged on the first and second auxiliary insulating layers 304 and 306 exposed between the color filters CF, respectively. The liner layer 308 may be conformally arranged on the top surfaces and the sidewalls of the color filters CF, and the top surfaces of the first and second auxiliary insulating layers 304 and 306 exposed between the color filters CF.

An air gap AG may be provided between the color filters CF. The color filters CF may be spaced apart from each other to form a space for forming an air gap AG. The air gap AG may be conformally arranged on the sidewalls of the color filters CF, and the top surfaces of the first and second auxiliary insulating layers 304 and 306 exposed between the color filters CF.

A capping layer 310 may be provided on top surfaces of the color filters CF. The capping layer 310 may be arranged on top surfaces and portions of sidewalls of the color filters CF. The capping layer 310 may include a portion arranged between the color filters CF. The capping layer 310 may be arranged on some regions of the sidewalls of the color filters CF. The capping layer 310 may be arranged on the liner layer 308 on the top surfaces and sidewalls of the color filters CF. For example, the capping layer 310 may include a low temperature oxide (LTO) that may be a kind of silicon oxide (SiO) layer. For example, the capping layer 310 may include a plasma-enhanced oxide (PEOX) layer.

An auxiliary insulating layer 320 may be provided on the capping layer 310. The auxiliary insulating layer 320 may be and/or may include a planarization layer arranged on the capping layer 310. The auxiliary insulating layer 320 may include, for example, at least one of a silicon oxide (SiO) layer-based material, a silicon nitride (SiN) layer-based material, a resin, and a combination thereof.

The microlenses ML may be arranged on the top surfaces of the color filters CF, respectively. The microlenses ML may vertically overlap the photoelectric conversion regions 110, respectively. In an embodiment, the microlenses ML may be connected to each other. The microlenses ML may be transparent and transmit light. The microlenses ML may have a convex shape to concentrate light incident on the unit pixel regions 101. The microlenses ML may include an organic material. For example, the microlenses ML may include a photoresist material or a thermosetting resin.

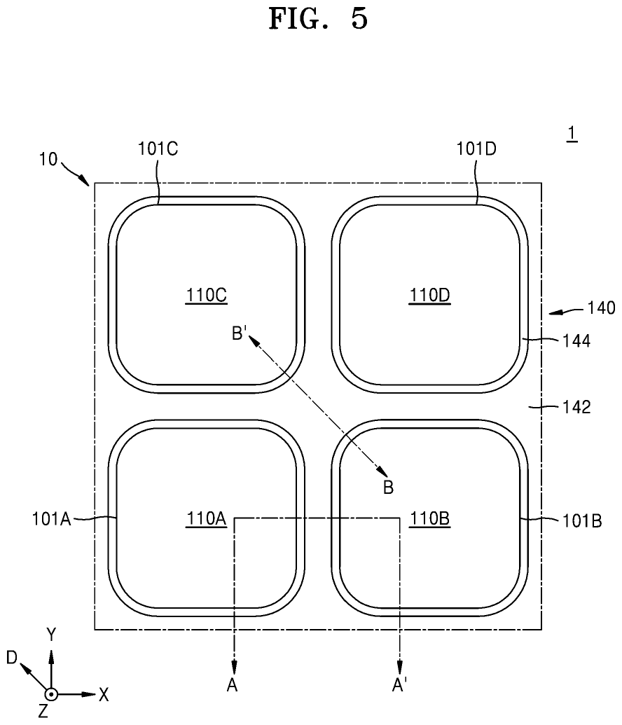

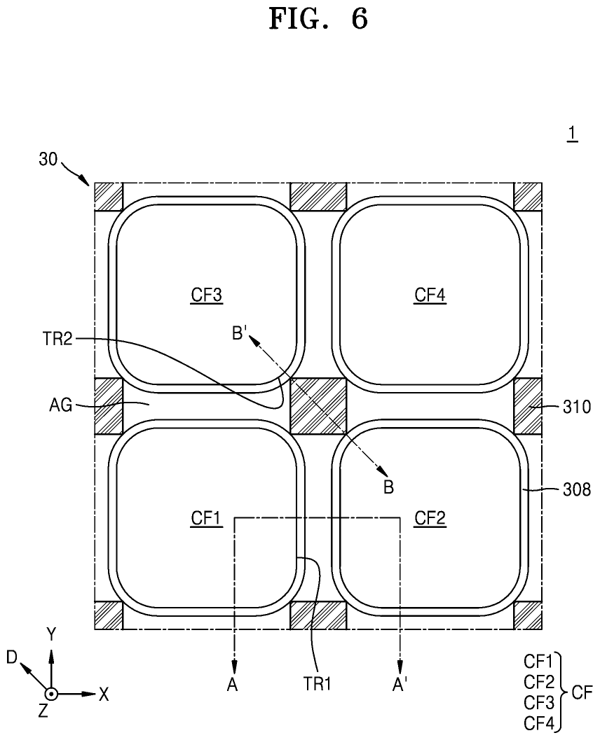

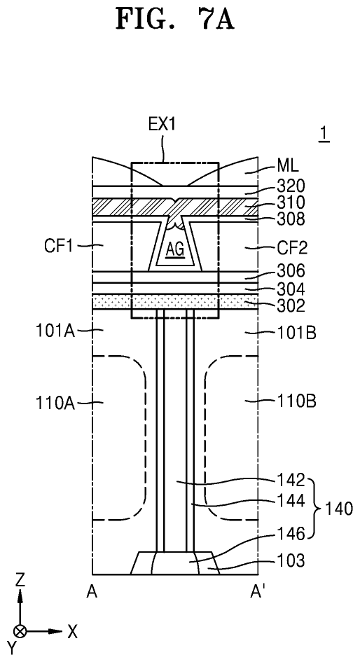

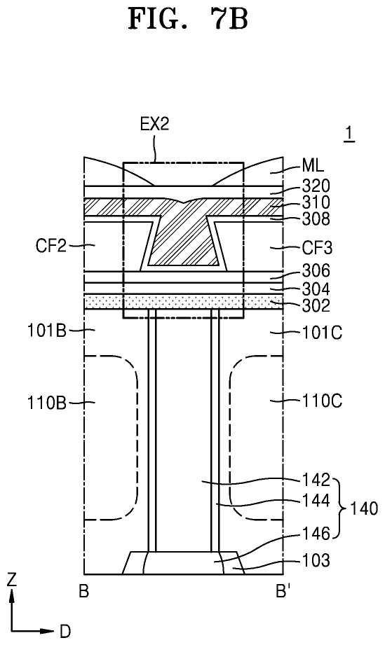

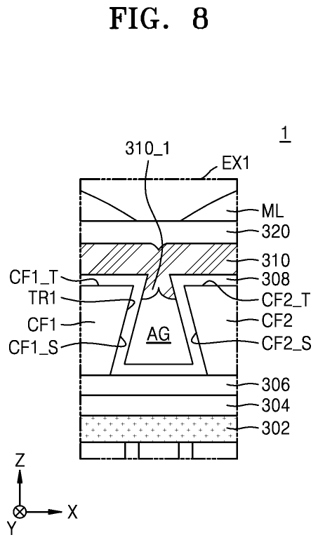

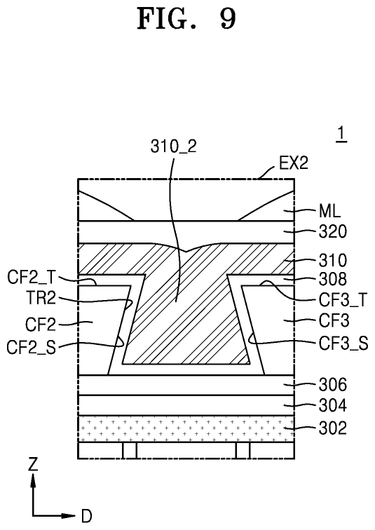

FIGS. 5 to 9 illustrate a portion of a pixel array region of the image sensor 1, according to embodiments. FIG. 5 is a cross-sectional view taken along line P-P′ of FIG. 4. FIG. 6 is a cross-sectional view taken along line Q-Q′ of FIG. 4. FIG. 7A is a cross-sectional view taken along line A-A′ of FIGS. 5 and 6. FIG. 7B is a cross-sectional view taken along line B-B′ of FIGS. 5 and 6. FIG. 8 is an enlarged cross-sectional view of a region EX1 of FIG. 7A. FIG. 9 is an enlarged cross-sectional view of a region EX2 of FIG. 7B.

Referring to FIG. 5, a plurality of photoelectric conversion regions 110 (e.g., a first photoelectric conversion region 110A, a second photoelectric conversion region 110B, a third photoelectric conversion region 110C, and a fourth photoelectric conversion region 110D) may be arranged in a lattice structure in the photoelectric conversion layer 10. The plurality of photoelectric conversion regions 110A to 110D may be arranged in a plurality of unit pixel regions 101 (e.g., a first unit pixel region 101A, a second unit pixel region 101B, a third unit pixel region 101C, and a fourth unit pixel region 101D), respectively. For example, the second photoelectric conversion region 110B may be arranged to be adjacent to the first photoelectric conversion region 110A in a first horizontal direction (X direction). The third photoelectric conversion region 110C may be arranged to be adjacent to the first photoelectric conversion region 110A in a second horizontal direction (Y direction). In addition, the fourth photoelectric conversion region 110D may be arranged to be adjacent to the first photoelectric conversion region 110A in a diagonal direction (D direction) of the first photoelectric conversion region 110A. The second photoelectric conversion region 110B and the third photoelectric conversion region 110C may be arranged to be adjacent to each other in the diagonal direction (D direction). The diagonal direction (D direction) may be a third horizontal direction crossing the first horizontal direction (X direction) and the second horizontal direction (Y direction). That is, the fourth photoelectric conversion region 110D may be arranged not to overlap the first photoelectric conversion region 110A in the first horizontal direction (X direction) and the second horizontal direction (Y direction). The fourth photoelectric conversion region 110D may be arranged to be adjacent to the second photoelectric conversion region 110B in the second horizontal direction (Y direction), and may be arranged to be adjacent to the third photoelectric conversion region 110C in the first horizontal direction (X direction).

In some embodiments, the pixel isolation structure 140 arranged in the vertical direction (Z direction) in the substrate 100 may define the plurality of unit pixel regions 101A to 101D. In some embodiments, the pixel isolation structure 140 may be arranged to surround each of the plurality of unit pixel regions 101A to 101D. The pixel isolation structure 140 may be arranged between any two of the plurality of photoelectric conversion regions 110A to 110D. The pixel isolation structure 140 may have a lattice shape between any two of the plurality of photoelectric conversion regions 110A to 110D arranged in a lattice structure. The pixel isolation structure 140 may extend in the first horizontal direction (X direction) and the second horizontal direction (Y direction) among the plurality of photoelectric conversion regions 110A to 110D arranged in a lattice structure.

Referring to FIG. 6, the first color filter CF1, the second color filter CF2, the third color filter CF3, and the fourth color filter CF4 may be arranged in a lattice structure in the light transmission layer 30. For example, the second color filter CF2 may be arranged to be adjacent to the first color filter CF1 in the first horizontal direction (X direction). The third color filter CF3 may be arranged adjacent to the first color filter CF1 in the second horizontal direction (Y direction). The fourth color filter CF4 may be arranged to be adjacent to the second color filter CF2 in the second horizontal direction (Y direction) and to be adjacent to the third color filter CF3 in the first horizontal direction (X direction). The fourth color filter CF4 may be arranged to be adjacent to the first color filter CF1 in the diagonal direction (D direction). The third color filter CF3 may be arranged to be adjacent to the second color filter CF2 in the diagonal direction (D direction).

In some embodiments, a first trench TR1 may be arranged between two of the first color filter CF1, the second color filter CF2, the third color filter CF3, and the fourth color filter CF4. That is, the first trench TR1 may be arranged between two of the first color filter CF1, the second color filter CF2, the third color filter CF3, and the fourth color filter CF4, in the horizontal direction (e.g., the first horizontal direction (X direction) and/or the second horizontal direction (Y direction)). For example, the first trench TR1 may be arranged between the first color filter CF1 and the second color filter CF2, between the first color filter CF1 and the third color filter CF3, between the second color filter CF2 and the fourth color filter CF4, between the first color filter CF1 and the fourth color filter CF4, and between the third color filter CF3 and the fourth color filter CF4.

In some embodiments, an air gap AG may be arranged in the first trench TR1 between two of the first color filter CF1, the second color filter CF2, the third color filter CF3, and the fourth color filter CF4. That is, an air gap AG may be arranged in the first trench TR1 between some two of the first color filter CF1, the second color filter CF2, the third color filter CF3, and the fourth color filter CF4, in the horizontal direction (e.g., the first horizontal direction (X direction) and/or the second horizontal direction (Y direction)). For example, an air gap AG may be arranged in the first trench TR1 between the first color filter CF1 and the second color filter CF2, between the first color filter CF1 and the third color filter CF3, between the second color filter CF2 and the fourth color filter CF4, and between the third color filter CF3 and the fourth color filter CF4.

In some embodiments, a second trench TR2 may be arranged between the other two of the first color filter CF1, the second color filter CF2, the third color filter CF3, and the fourth color filter CF4. That is, the second trench TR2 may be arranged between the other two of the first color filter CF1, the second color filter CF2, the third color filter CF3, and the fourth color filter CF4 in the diagonal direction (e.g., the diagonal direction (D direction)). For example, the second trench TR2 may be arranged between the first color filter CF1 and the fourth color filter CF4, and between the second color filter CF2 and the third color filter CF3, in the diagonal directions (e.g., the diagonal direction (D direction)).

In some embodiments, the width of the first trench TR1 may be less than the width of the second trench TR2. That is, the width of the first trench TR1 in the horizontal direction (e.g., the first horizontal direction (X direction) and/or the second horizontal direction (Y direction)) may be less than the width of the second trench TR2 in the diagonal direction (e.g., the diagonal direction (D direction)).

In some embodiments, a capping layer 310 may be arranged between two of the first color filter CF1, the second color filter CF2, the third color filter CF3, and the fourth color filter CF4. That is, the capping layer 310 may be arranged between two of the first color filter CF1, the second color filter CF2, the third color filter CF3, and the fourth color filter CF4 in the diagonal direction (e.g., the diagonal direction (D direction)). For example, the capping layer 310 may be arranged between the second color filter CF2 and the third color filter CF3, and between the first color filter CF1 and the fourth color filter CF4.

Each of the first color filter CF1, the second color filter CF2, the third color filter CF3, and the fourth color filter CF4 may include one of red, green, and blue color filters. For example, each of the first color filter CF1 and the fourth color filter CF4 may include a green color filter, the second color filter CF2 may include a red color filter, and the third color filter CF3 may include a blue color filter. However, this is only for convenience of explanation, and the present disclosure not limited thereto. For example, depending on the unit pixel, the red, green, or blue color filters may be arranged in different ways. Alternatively or additionally, depending on the unit pixel, each of the first color filter CF1, the second color filter CF2, the third color filter CF3, and the fourth color filter CF4 may include, for example, one of cyan, magenta, and yellow color filters.

Referring to FIGS. 7A and 7B together, the first color filter CF1, the second color filter CF2, the third color filter CF3, and the fourth color filter CF4 may be arranged on the plurality of unit pixel regions 101A to 101D, respectively. For example, the first color filter CF1, the second color filter CF2, the third color filter CF3, and the fourth color filter CF4 may overlap the plurality of unit pixel regions 101A to 101D in a vertical direction (Z direction), respectively.

Referring to FIG. 8 together with FIGS. 7A and 7B, a first trench TR1 may be arranged between the first color filter CF1 and the second color filter CF2. That is, the first trench TR1 may be defined by the first color filter CF1 and the second color filter CF2. For example, the first trench TR1 may be defined by the sidewall CF1_S of the first color filter CF1 and the sidewall CF2_S of the second color filter CF2.

In some embodiments, the first trench TR1 may include a bottom surface on the top surface of the first and second auxiliary insulating layers 304 and 306, and both of the sidewall CF1_S of the first color filter CF1 and the sidewall CF2_S of the second color filter CF2. In some embodiments, the width of the lower portion of the first trench TR1 in the first horizontal direction (X direction) may be greater than the width of the upper portion in the first horizontal direction (X direction). For example, the width in the first horizontal direction (X direction) may decrease away from the bottom surface in the vertical upward direction (e.g., +Z direction). In some embodiments, the width of the first trench TR1 in the first horizontal direction (X direction) may be constant, or may increase in the vertical upward direction (e.g., +Z direction).

In some embodiments, an air gap AG may be placed in the first trench TR1. That is, an air gap AG may be arranged in the lower portion of the first trench TR1.

In some embodiments, the air gap AG may improve (e.g., prevent or suppress) a cross-talk phenomenon between color filters, including a material with a low refractive index (e.g., air with a refractive index of one (1)). For example, it may be possible to improve (e.g., prevent or suppress) the flow of the optical signal entering the first color filter CF1 to the second color filter CF2. In addition, as the crosstalk phenomenon improves (e.g., is prevented or suppressed), noise may decrease, when compared to a related image sensor. That is, according to embodiments, the image sensor 1 may have an improved performance and reliability when compared to a related image sensor.

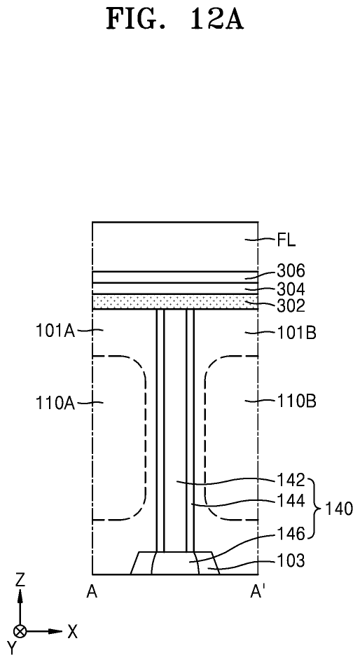

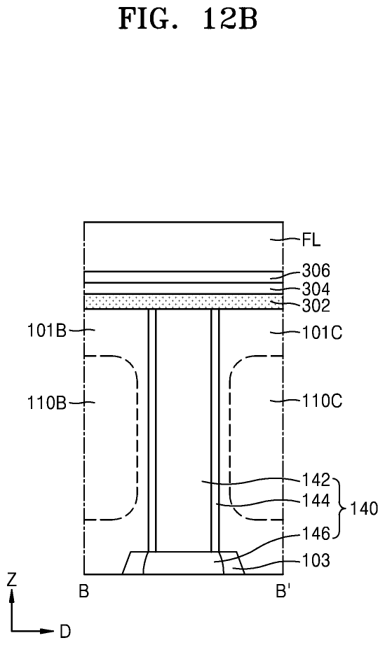

In some embodiments, the liner layer 308 may be arranged on the bottom surface and both sidewalls of the first trench TR1, the top surface CF1_T of the first color filter CF1, and the top surface CF2_T of the second color filter CF2. For example, the liner layer 308 may cover the sidewall CF1_S of the first color filter CF1 and the sidewall CF2_S of the second color filter CF2, which are exposed by the first trench TR1. As another example, in a process for forming the image sensor 1, which is described below with reference to FIGS. 12A to 18B, the liner layer 308 may cover the first color filter CF1 and the second color filter CF2 to prevent defects due to a fume formed at a high temperature.

The image sensor 1, according to embodiments, may include the liner layer 308 to prevent and/or reduce fume-induced defects, when compared to a related image sensor. That is, according to embodiments, the image sensor 1 may have an improved performance and reliability when compared to a related image sensor.

In some embodiments, the liner layer 308 may be conformally arranged on the bottom surface and both sidewalls of the first trench TR1, the top surface CF1_T of the first color filter CF1, and the top surface CF2_T of the second color filter CF2. For example, the liner layer 308 may be formed by an atomic layer deposition (ALD). In an embodiment, the liner layer 308 may have a substantially constant and/or a same thickness. For example, the liner layer 308 may have a thickness less than several hundred angstroms (Å). For example, the liner layer 308 may have a thickness less than about 100 Å.

In an embodiment, the liner layer 308 may include an oxide or nitride. For example, the liner layer 308 may include, but not be limited to, a silicon oxide (SiO), a silicon nitride (SiN), and/or a metal oxide.

In some embodiments, the capping layer 310 may be arranged on the top surface CF1_T of the first color filter CF1 and the top surface CF2_T of the second color filter CF2. That is, the capping layer 310 may be arranged on the liner layer 308 on the top surface CF1_T of the first color filter CF1 and the top surface CF2_T of the second color filter CF2.

In some embodiments, the capping layer 310 may include a first sub-portion 310_1 arranged in the first trench TR1. For example, the first sub-portion 310_1 may be arranged between the first color filter CF1 and the second color filter CF2. As another example, the first sub-portion 310_1 may overlap the first color filter CF1 and the second color filter CF2 in the first horizontal direction (X direction). That is, the first sub-portion 310_1 of the capping layer 310 may be arranged in the upper portion of the first trench TR1. The capping layer 310 may not be arranged in the lower portion of the first trench TR1, and thus an air gap AG may be formed in the lower portion of the first trench TR1. The first sub-portion 310_1 of the capping layer 310 may be integrally formed with the remaining portion of the capping layer 310 (e.g., a portion arranged on the first color filter CF1 and the second color filter CF2).

In some embodiments, the first sub-portion 310_1 of the capping layer 310 may not be in contact with the liner layer 308 on the bottom surface of the first trench TR1.

In some embodiments, as the capping layer 310 includes the first sub-portion 310_1 arranged in the first trench TR1, a vertical level of a portion overlapping the first trench TR1 in the vertical direction (Z direction) of the capping layer 310 may be lower than a vertical level of a portion not overlapping the first trench TR1 in the vertical direction (Z direction) of the capping layer 310. For example, a vertical level of a portion overlapping the first trench TR1 in the vertical direction (Z direction) of the capping layer 310 may be lower than a vertical level of a portion overlapping the color filters (e.g., the first color filter CF1 and the second color filter CF2) in the vertical direction (Z direction) of the capping layer 310.

In some embodiments, the air gap AG between the first color filter CF1 and the second color filter CF2 may be surrounded by the liner layer 308 and the capping layer 310 within the first trench TR1. For example, the air gap AG between the first color filter CF1 and the second color filter CF2 may be surrounded by the liner layer 308 and the first sub-portion 310_1 of the capping layer 310 in the first trench TR1. As another example, the upper portion of the air gap AG may be surrounded by the first sub-portion 310_1 of the capping layer 310, and the lower portion of the air gap AG may be surrounded by the liner layer 308. In some embodiments, an upper portion of the air gap AG may be in contact with the first sub-portion 310_1 of the capping layer 310, and a lower portion thereof may be in contact with the liner layer 308. For example, in some embodiments, the lower portion of the air gap AG may be in contact with the liner layer 308 on the bottom surface of the first trench TR1.

Referring to FIG. 9 together with FIGS. 7A and 7B, a second trench TR2 may be arranged between the second color filter CF2 and the third color filter CF3. The second trench TR2 may be defined by the second color filter CF2 and the third color filter CF3. For example, the second trench TR2 may be defined by the sidewall CF2_S of the second color filter CF2 and the sidewall CF3_S of the third color filter CF3.

In some embodiments, the second trench TR2 may include a bottom surface on the top surface of the first and second auxiliary insulating layers 304 and 306 and both of the sidewall CF2_S of the second color filter CF2 and the sidewall CF3_S of the third color filter CF3.

In some embodiments, the air gap AG may not be arranged in the second trench TR2.

In some embodiments, the liner layer 308 may be arranged on the bottom surface and both sidewalls of the second trench TR2, the top surface CF2_T of the second color filter CF2, and the top surface CF3_T of the third color filter CF3. For example, the liner layer 308 may cover the sidewall CF2_S of the second color filter CF2 and the sidewall CF3_S of the third color filter CF3, which may be exposed by the second trench TR2. In some embodiments, the liner layer 308 may be conformally arranged on the bottom surface and both sidewalls of the second trench TR2, the top surface CF2_T of the second color filter CF2, and the top surface CF3_T of the third color filter CF3.

In some embodiments, the capping layer 310 may be arranged on the top surface CF2_T of the second color filter CF2 and the top surface CF3_T of the third color filter CF3. That is, the capping layer 310 may be arranged on the liner layer 308 on the top surface CF2_T of the second color filter CF2 and the top surface CF3_T of the third color filter CF3.

In some embodiments, the capping layer 310 may include a second sub-portion 310_2 arranged in the second trench TR2. For example, the second sub-portion 310_2 may be arranged between the second color filter CF2 and the third color filter CF3. That is, the second sub-portion 310_2 may be arranged in the upper and lower portions of the second trench TR2. For example, the second sub-portion 310_2 may fill the inside of the second trench TR2. As another example, the second sub-portion 310_2 may fill the remaining space in the second trench TR2 on the liner layer 308.

In some embodiments, as the capping layer 310 includes the second sub-portion 310_2 arranged in the second trench TR2, a vertical level of a portion overlapping the second trench TR2 in the vertical direction (Z direction) of the capping layer 310 may be lower than a vertical level of a portion not overlapping the second trench TR2 in the vertical direction (Z direction) of the capping layer 310.

In some embodiments, the second sub-portion 310_2 arranged in the second trench TR2 of the capping layer 310 may be arranged between the plurality of color filters CF (e.g., the second color filter CF2 and the third color filter CF3) in the diagonal direction (D direction) in a plan view, and may serve to physically support the components. That is, according to embodiments, the image sensor 1 may have an improved performance and reliability when compared to a related image sensor.

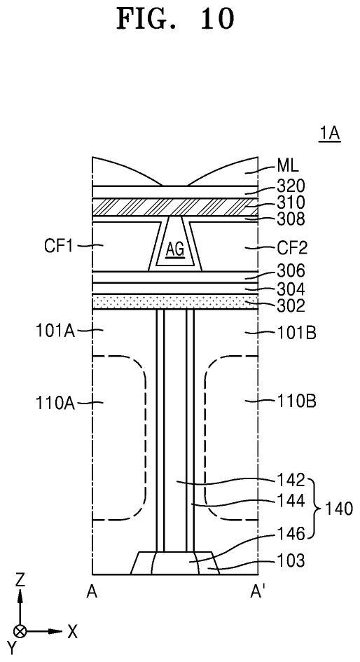

FIG. 10 is a cross-sectional view of a pixel array region of an image sensor 1A, according to embodiments.

The image sensor 1A may include and/or may be similar in many respects to the image sensor 1 described above with reference to FIGS. 4 to 9, and may include additional features not mentioned above. Consequently, repeated descriptions of the image sensor 1 described above with reference to FIGS. 4 to 9 may be omitted for the sake of brevity.

Referring to FIG. 10, an air gap AG may be arranged between the first color filter CF1 and the second color filter CF2. The liner layer 308 may cover the top surfaces and sidewalls of the first color filter CF1 and the second color filter CF2, and the capping layer 310 may cover the top surfaces of the first color filter CF1 and the second color filter CF2 on the liner layer 308.

That is, the capping layer 310 may not be arranged between the first color filter CF1 and the second color filter CF2. For example, the capping layer 310 may not overlap the first color filter CF1 and the second color filter CF2 in the first horizontal direction (X direction).

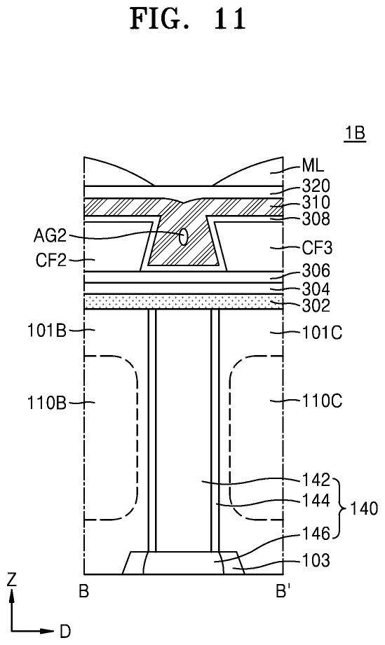

FIG. 11 is a cross-sectional view of a pixel array region of an image sensor 1B, according to embodiments. Hereinafter, differences from the image sensor 1 described with reference to FIGS. 4 to 9 are mainly described.

The image sensor 1B may include and/or may be similar in many respects to the image sensor 1 and the image sensor 1A described above with reference to FIGS. 4 to 10, and may include additional features not mentioned above. Consequently, repeated descriptions of the image sensor 1 and the image sensor 1A described above with reference to FIGS. 4 to 10 may be omitted for the sake of brevity.

Referring to FIG. 11, the liner layer 308 may cover the top surfaces and sidewalls of the first color filter CF1 and the second color filter CF2, and the capping layer 310 may cover the top surfaces of the first color filter CF1 and the second color filter CF2 on the liner layer 308.

In some embodiments, a second air gap AG2 may be arranged between the second color filter CF2 and the third color filter CF3. That is, the second air gap AG2 may be surrounded by the capping layer 310 between the second color filter CF2 and the third color filter CF3. The second air gap AG2 may not be in contact with the liner layer 308 between the second color filter CF2 and the third color filter CF3. In some embodiments, the second air gap AG2 may be in contact with the liner layer 308 between the second color filter CF2 and the third color filter CF3.

FIGS. 12A to 18B are cross-sectional views illustrating a process of manufacturing an image sensor 1, according to embodiments.

Referring to FIGS. 12A and 12B together with FIG. 4, unit pixel regions 101 (e.g., the first unit pixel region 101A, the second unit pixel region 101B, and the third unit pixel region 101C) may be defined by the pixel isolation structure 140 and photoelectric conversion regions 110 (e.g., the first photoelectric conversion region 110A, the second photoelectric conversion region 110B, and the third photoelectric conversion region 110C) in the first to third unit pixel regions 101A to 101C may be provided in the substrate 100. A rear insulating layer 302 and auxiliary insulating layers (e.g., first auxiliary insulating layers 304 and second auxiliary insulating layers 306) may be sequentially arranged on the second surface 100b of the substrate 100. A fence layer FL may be formed on the first and second auxiliary insulating layers 304 and 306. For example, the first auxiliary insulating layers 304 may be formed on the second surface 100b of the substrate 100, and the second auxiliary insulating layers 306 may be formed on the first auxiliary insulating layers 304, and then the fence layer FL may be formed on the second auxiliary insulating layers 306. The fence layer FL may include, for example, an oxide.

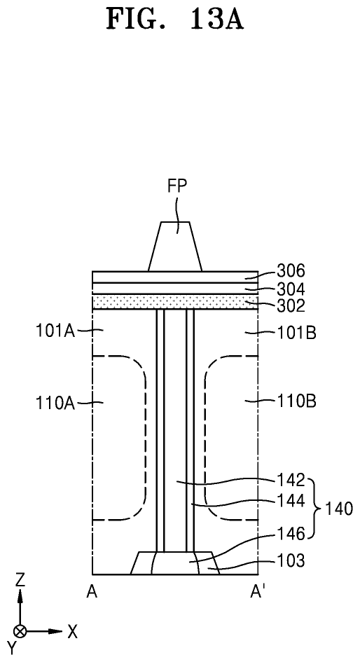

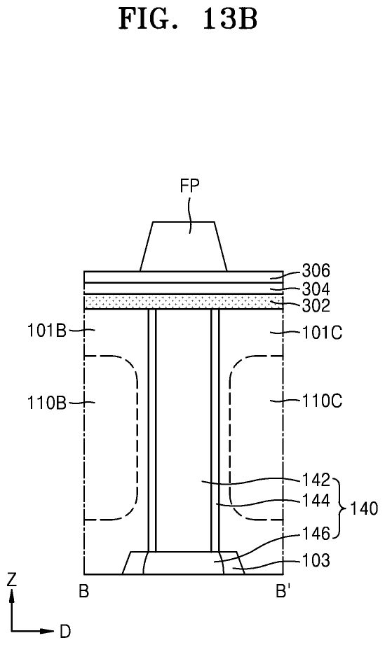

Referring to FIGS. 13A and 13B together with FIG. 3, a fence pattern FP may be formed by patterning the fence layer FL. Some regions of the first and second auxiliary insulating layers 304 and 306 may be exposed by the fence pattern FP. The fence pattern FP may expose a region in which color filters CF (e.g., the first color filter CF1 and the second color filter CF2 of FIG. 4) are to be formed.

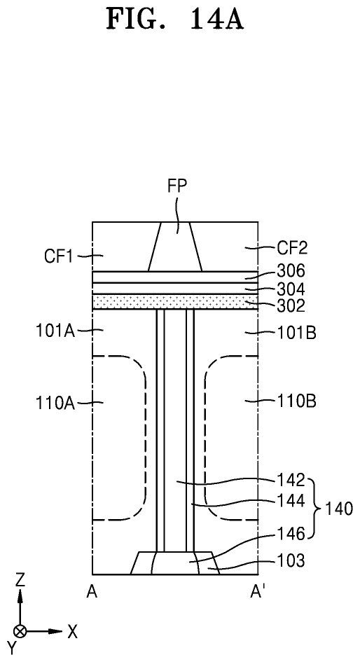

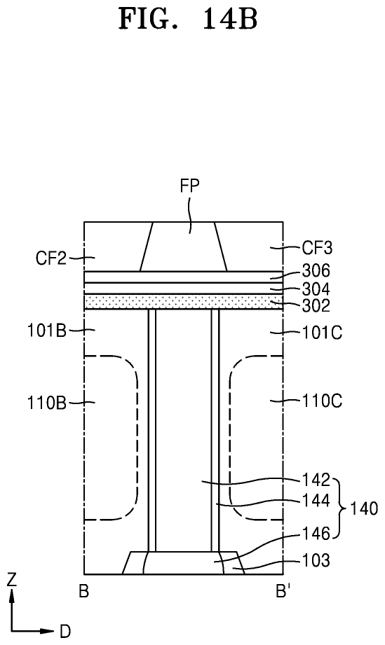

Referring to FIGS. 14A and 14B, the color filters CF (e.g., the first color filter CF1, the second color filter CF2, and the third color filter CF3) may be formed. That is, the color filters CF (e.g., the first color filter CF1, the second color filter CF2, and the third color filter CF3) may be formed in a partial region exposed by the fence patterns FP. For example, the first color filter CF1 may be formed on the first photoelectric conversion region 110A, the second color filter CF2 may be formed on the second photoelectric conversion region 110B, and the third color filter CF3 may be formed on the third photoelectric conversion region 110C.

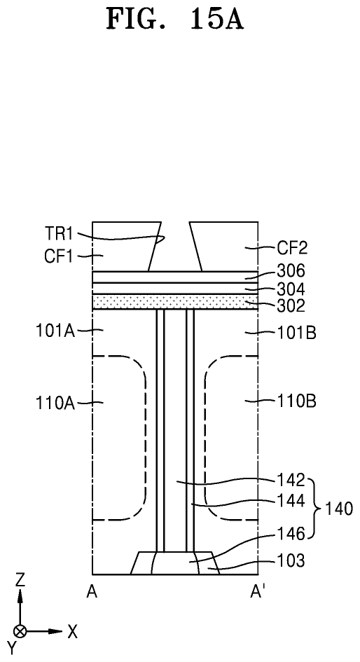

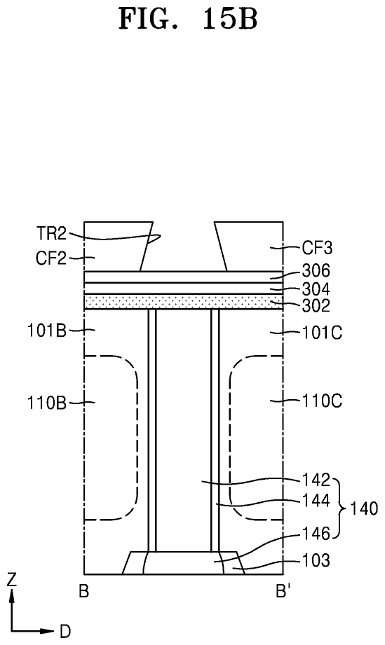

Referring to FIGS. 15A and 15B, the fence patterns FP may be removed. For example, the fence patterns FP may be removed using a wet etching process. Accordingly, the first trench TR1 and the second trench TR2 may be formed. That is, the first trench TR1 may be formed between the first color filter CF1 and the second color filter CF2, and the second trench TR2 may be formed between the second color filter CF2 and the third color filter CF3. The sidewall of each of the first color filter CF1, the second color filter CF2, and the third color filter CF3 may be exposed by the first trench TR1 and the second trench TR2.

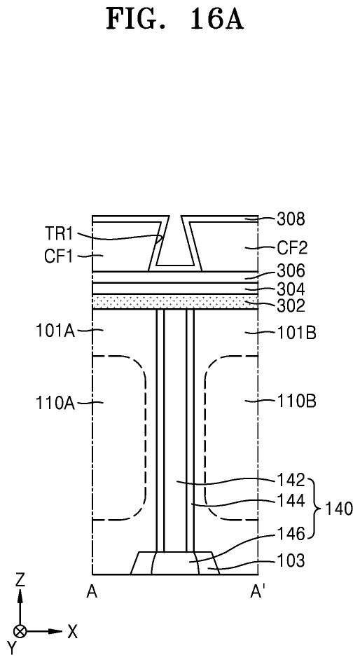

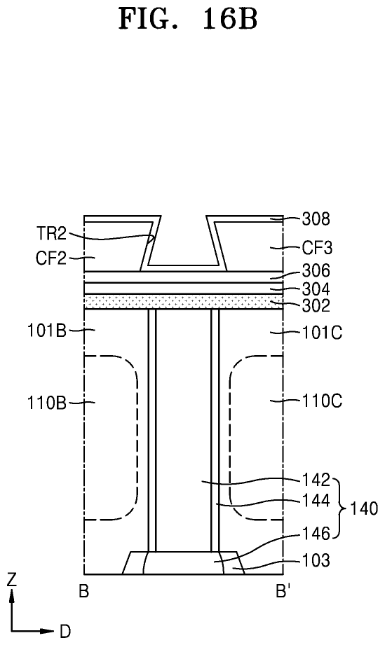

Referring to FIGS. 16A and 16B, the liner layer 308 covering the sidewall of each of the first color filter CF1, the second color filter CF2, and the third color filter CF3 may be formed. That is, the liner layer 308 may be conformally formed on the bottom surface and both sidewalls of the first trench TR1, the bottom surface and both sidewalls of the second trench TR2, and the top surface of each of the first color filter CF1, the second color filter CF2, and the third color filter CF3.

As described above, the process of forming the liner layer 308 may be performed by an atomic layer deposition process. For example, the atomic layer deposition process may be performed at a temperature of about 50 degrees Celsius (° C.). Therefore, while the atomic layer deposition process is performed, fumes may not be formed or less fumes may be formed in the color filters CF (e.g., the first color filter CF1, the second color filter CF2, and the third color filter CF3)

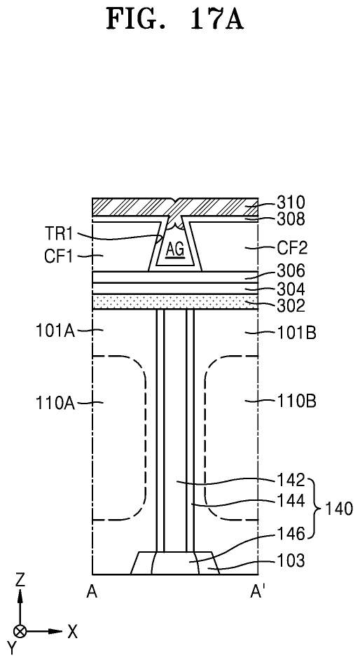

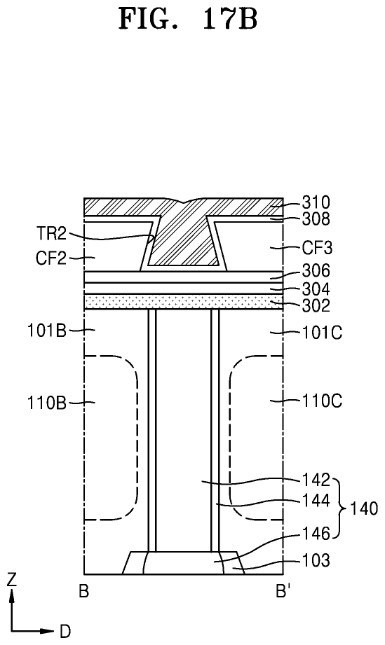

Referring to FIGS. 17A and 17B, the capping layer 310 may be formed above top surfaces of the color filters CF (e.g., the first color filter CF1, the second color filter CF2, and the third color filter CF3). That is, the capping layer 310 may be formed above the top surface of each of the first color filter CF1, the second color filter CF2, and the third color filter CF3. The capping layer 310 may be formed on the liner layer 308 on each of the first color filter CF1, the second color filter CF2, and the third color filter CF3.

The process of forming the capping layer 310 may be performed by a chemical vapor deposition (CVD) process. For example, the process of forming the capping layer 310 may be performed by a plasma enhanced chemical vapor deposition (PECVD) process. For example, the process of forming the capping layer 310 may be performed at a temperature of about 220° C. or less.

That is, the capping layer 310 may include a portion arranged between the first color filter CF1 and the second color filter CF2. The capping layer 310 may include a portion arranged between the second color filter CF2 and the third color filter CF3. In such a case, the entrance of the trench (e.g., the first trench TR1) between the first color filter CF1 and the second color filter CF2 may be narrow, so that all of the capping layers 310 may not be arranged in the space within the trench, and a portion of the capping layer 310 may be arranged only in the upper portion of the trench.

In such a case, since the capping layer 310 is arranged only in a portion of the trench between the first color filter CF1 and the second color filter CF2, an air gap AG may be formed between the first color filter CF1 and the second color filter CF2.

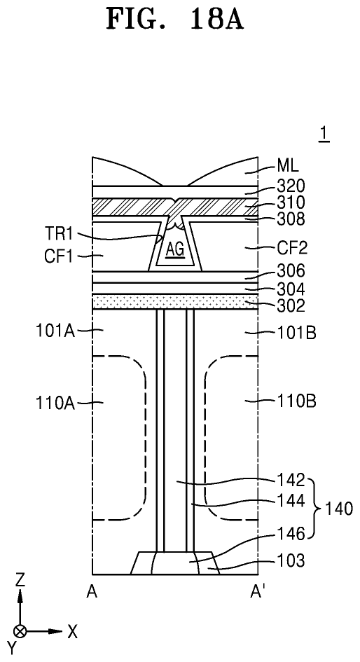

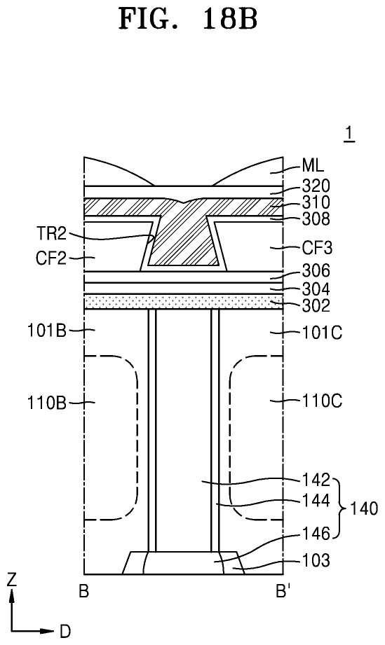

Referring to FIGS. 18A and 18B, an auxiliary insulating layer 320 and microlenses ML may be formed on the capping layer 310 to manufacture the image sensor 1.

While the present disclosure has been particularly shown and described with reference to embodiments thereof, it is to be understood that various changes in form and details may be made therein without departing from the spirit and scope of the following claims.

What is claimed is:

1. An image sensor, comprising:
a substrate comprising a photoelectric conversion region;
a first color filter above the substrate;
a second color filter adjacent to the first color filter in a first horizontal direction, and above the substrate;
a plurality of liner layers on an upper surface and a sidewall of each of the first color filter and the second color filter;
an air gap between the first color filter and the second color filter; and
a capping layer on the upper surface of each of the first color filter and the second color filter.

2. The image sensor of claim 1, further comprising:
a third color filter adjacent to the first color filter in a second horizontal direction crossing the first horizontal direction,
wherein the capping layer comprises a first sub-portion between the second color filter and the third color filter.

3. The image sensor of claim 2, wherein the air gap is not between the second color filter and the third color filter.

4. The image sensor of claim 1, wherein the capping layer comprises a second sub-portion on an upper portion of the air gap and between the first color filter and the second color filter.

5. The image sensor of claim 1, wherein the plurality of liner layers comprise at least one of an oxide layer and a nitride layer.

6. The image sensor of claim 1, wherein the capping layer comprises a plasma enhanced oxide (PEOX) layer.

7. An image sensor, comprising:
a substrate comprising a photoelectric conversion region;
a first color filter above the substrate;
a second color filter adjacent to the first color filter in a first horizontal direction, and above the substrate;
a first trench between the first color filter and the second color filter;
a first plurality of liner layers conformally disposed on a bottom surface of the first trench, a first sidewall of the first trench, and a second sidewall of the first trench;
a first air gap in the first trench; and
a plurality of capping layers on the first air gap, a top surface of the first color filter, and a top surface of the second color filter.

8. The image sensor of claim 7, further comprising:
a third color filter adjacent to the first color filter in a second horizontal direction crossing the first horizontal direction;
a second trench between the second color filter and the third color filter; and
a second plurality of liner layers conformally disposed on a bottom surface of the second trench, a first sidewall of the second trench, and a second sidewall of the second trench.

9. The image sensor of claim 7, further comprising:
a third color filter adjacent to the first color filter in a second horizontal direction crossing the first horizontal direction; and
a second trench between the second color filter and the third color filter,
wherein each capping layer of the plurality of capping layers comprises a first sub-portion in the second trench.

10. The image sensor of claim 9, wherein an air gap is not between the second color filter and the third color filter.

11. The image sensor of claim 7, wherein the plurality of capping layers comprise a second sub-portion in an upper portion of the first trench.

12. The image sensor of claim 7, wherein the first plurality of liner layers comprise a portion on the top surface of the first color filter and the top surface of the second color filter.

13. The image sensor of claim 7, wherein the first trench is defined by a sidewall of the first color filter and a sidewall of the second color filter.

14. The image sensor of claim 7, wherein the first air gap is at least partially surrounded by the first plurality of liner layers and the plurality of capping layers.

15. The image sensor of claim 7, wherein the first plurality of liner layers comprise at least one of an oxide layer and a nitride layer.

16. The image sensor of claim 7, further comprising:
a third color filter adjacent to the first color filter in a second horizontal direction crossing the first horizontal direction;
a third trench between the first color filter and the third color filter;
a second air gap in the third trench; and
a third plurality of liner layers conformally disposed on a bottom surface of the third trench, a first sidewall of the third trench, and a second sidewall of the third trench.

17. An image sensor, comprising:
a substrate comprising a photoelectric conversion region;
a first color filter above the substrate;
a second color filter adjacent to the first color filter in a first horizontal direction, above the substrate;
a third color filter adjacent to the first color filter in a second horizontal direction crossing the first horizontal direction;
a first trench between the first color filter and the second color filter;
a second trench between the second color filter and the third color filter;
a plurality of liner layers conformally disposed on a bottom surface of the first trench, a first sidewall of the first trench, a second sidewall of the first trench, a bottom surface of the second trench, a first sidewall of the second trench, and a second sidewall the second trench;
a first air gap in the first trench; and
a plurality of capping layers on a top surface of the first color filter, a top surface of the second color filter, and a top surface of the third color filter, and in the second trench.

18. The image sensor of claim 17, wherein the first air gap is at least partially surrounded by the plurality of liner layers and the plurality of capping layers.

19. The image sensor of claim 17, wherein the first air gap is not disposed in the second trench.

20. The image sensor of claim 17, wherein the first air gap is in contact with the plurality of liner layers.
